(19) United States
(12) Patent Application Publication
(10) Pub. No.: US 2023/0282506 A1
(43) Pub. Date: Sep. 7, 2023

(54) BIASABLE ROTATING PEDESTAL

(71) Applicant: Applied Materials, Inc., Santa Clara, CA (US)

(72) Inventors: Anantha Subramani, San Jose, CA (US); Yang Guo, Fremont, CA (US); Seyyed Fazeli, Santa Clara, CA (US); Ramcharan Sundar, Chennai (IN); Arun Kumar Kotrappa, Davanagere (IN)

(21) Appl. No.: 17/685,272

(22) Filed: Mar. 2, 2022

(51) Int. Cl. H01L 21/683; H01J 37/32; C23C 14/28; C23C 14/50

(52) U.S. Cl. CPC H01L 21/6833; H01J 37/32724; C23C 14/28; C23C 14/505; H01J 2237/2007; H01J 2237/20214; H01J 2237/20235; H01J 2237/332

(57) ABSTRACT

Embodiments disclosed herein include an electrostatic chuck. In an embodiment, the electrostatic chuck comprises a pedestal with a support surface for supporting a substrate and a second surface opposite from the support surface, and chucking electrode within the pedestal. In an embodiment, a biasing electrode is within the pedestal, and a heating element is within the pedestal. In an embodiment, the electrostatic chuck further comprises a shaft coupled to the second surface of the pedestal, and a rotation assembly coupled to the shaft to rotate the shaft and the pedestal.

### BACKGROUND

### 1) Field

Embodiments relate to the field of semiconductor manufacturing and, in particular, to a semiconductor processing tool with a rotating pedestal.

### 2) Description of Related Art

Rotating pedestals are used in semiconductor manufacturing environments in order to provide tools that enable highly uniform outcomes on the substrate that is being processed in the tool. In existing tools, the rotating pedestal can comprise a electrostatic chucking electrode and a biasing electrode. The biasing electrode may be electrically coupled to a stationary plate with a wireless configuration. For example, the stationary plate may be capacitively coupled to the biasing electrode. As such, any direct electrical coupling across a conductor is omitted, and the biasing electrode is free to rotate with the pedestal.

Additionally, the electrostatic chucking electrode can be powered by current that passes through a bearing assembly of the rotating pedestal. This facilitates providing power to the chucking electrode while rotating the pedestal. For example, power can be drawn from a DC power source and routed to the bearing assembly. Current flows through the bearing assembly and is subsequently routed to the chucking electrodes via chucking power lines disposed within an interior of the shaft below the pedestal.

### SUMMARY

Embodiments disclosed herein include an electrostatic chuck. In an embodiment, the electrostatic chuck comprises a pedestal with a support surface for supporting a substrate and a second surface opposite from the support surface, and chucking electrode within the pedestal. In an embodiment, a biasing electrode is within the pedestal, and a heating element is within the pedestal. In an embodiment, the electrostatic chuck further comprises a shaft coupled to the second surface of the pedestal, and a rotation assembly coupled to the shaft to rotate the shaft and the pedestal.

Embodiments may further include a semiconductor tool. In an embodiment, the semiconductor tool comprises a chamber, and a first shaft through the chamber, where a baffle between the first shaft and the chamber seals the chamber. In an embodiment, the semiconductor tool further comprises a second shaft within the first shaft, and a pedestal over a first end of the second shaft within the chamber. In an embodiment, the semiconductor tool further comprises a rotation assembly coupled to the second shaft to rotate the second shaft and the pedestal relative to the first shaft.

Embodiments may further include a semiconductor tool that comprises a chamber, and a pedestal within the chamber. In an embodiment, the pedestal comprises a chucking electrode, a bias electrode, and a heating element. In an embodiment, a first shaft is through a bottom of the chamber, and a second shaft is through the bottom of the chamber and within the first shaft. In an embodiment, the pedestal is coupled to the second shaft. In an embodiment, a baffle is between a portion of the first shaft and the chamber to seal the chamber. In an embodiment, a vacuum feedthrough is at an end of the second shaft opposite from the pedestal, and a radio frequency (RF) rotary feedthrough is below the vacuum feedthrough.

### BRIEF DESCRIPTION OF THE DRAWINGS

FIG. 1 is cross-sectional illustration of a semiconductor processing tool, in accordance with an embodiment.

FIG. 2 is a cross-sectional illustration of the semiconductor processing tool that more clearly illustrates components of the rotating pedestal, in accordance with an embodiment.

FIG. 3A is a cross-sectional illustration of an RF rotary feedthrough, in accordance with an embodiment.

FIG. 3B is a plan view illustration of the RF rotary feedthrough, in accordance with an embodiment.

FIG. 4 is a cross-sectional illustration of a semiconductor processing tool that illustrates the electrical routing through the central shaft to components within the pedestal, in accordance with an embodiment.

FIG. 5 illustrates a block diagram of an exemplary computer system that may be used in conjunction with a processing tool, in accordance with an embodiment.

### DETAILED DESCRIPTION

Systems described herein include a semiconductor tool that includes a rotatable pedestal. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, rotating pedestal architectures currently exist in some semiconductor processing tools. However, the powered components within the pedestal are limited. For example, capacitive coupling can be used to power the biasing electrode, and current can pass over bearings in order to power the electrostatic chucking electrodes. However, high current components of the semiconductor processing tool are not compatible with capacitive coupling or passing power over bearings. For example, heating elements (e.g., lamps, resistive heating elements, etc.) require high currents in order to provide the needed heat to the system.

In existing processing tools, the heating elements are stationary with respect to the rotating pedestal. As such, the current provided to the heating elements does not need to pass across a junction between a stationary component and a rotating component. However, in some processing tools it may be desirable to integrate the heating element into the pedestal. For example, in ultra-low vacuum chambers, it may be necessary to move the heating element into the pedestal in order to mitigate the ability of plasma to ignite below the pedestal. Accordingly, the heating elements will rotate with the pedestal and need an electrical connection that can be maintained across a junction between a stationary component and a rotating component.

Existing solutions (e.g., passing the current over a bearing, or capacitively coupling two plates) is not suitable for such high current applications. Accordingly, embodiments disclosed herein include a slip-ring architecture. The slip-ring architecture allows for high currents to be passed between a stationary component and a rotating component. In some embodiments, a plurality of slip-ring structures may be stacked on each other in order to provide power to a plurality of components (e.g., electrostatic chucking electrodes, biasing electrodes, heating elements, etc.). In a particular embodiment, seven or more slip-ring structures may be used.

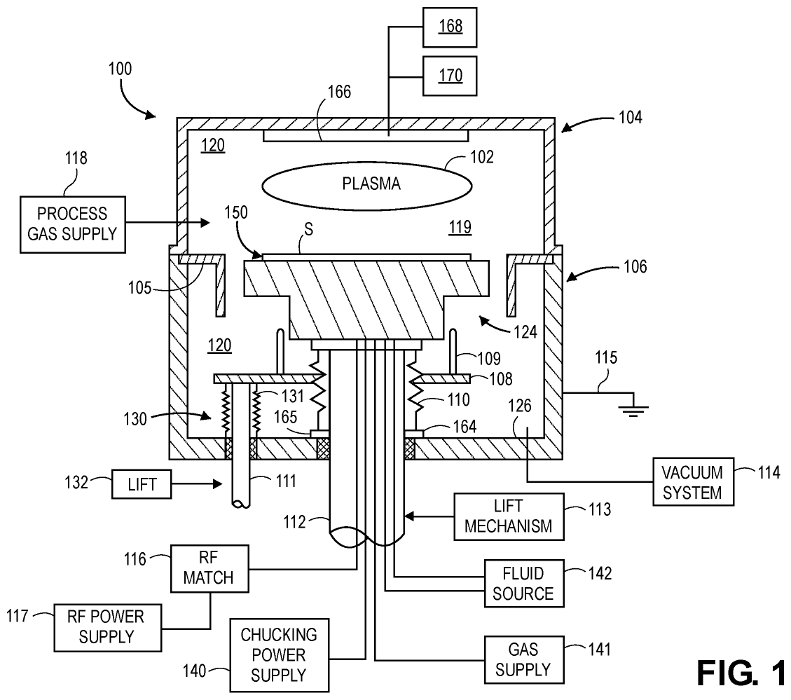

Referring now to FIG. 1, a schematic cross-sectional view of plasma processing chamber is shown, in accordance with some embodiments of the present disclosure. In some embodiments, the plasma processing chamber is a physical vapor deposition (PVD) processing chamber. However, other types of processing chambers (e.g., chemical vapor deposition (CVD) chambers, atomic layer deposition (ALD) chambers, and the like) can also use or be modified for use with embodiments of the inventive electrostatic chuck described herein.

The chamber 100 is a vacuum chamber which is suitably adapted to maintain sub-atmospheric pressures within a chamber interior volume 120 during substrate processing. The chamber 100 includes a chamber body 106 covered by a lid 104 which encloses a processing volume 119 located in the upper half of chamber interior volume 120. The chamber 100 may also include one or more shields 105 circumscribing various chamber components to prevent unwanted reaction between such components and ionized process material. The chamber body 106 and lid 104 may be made of metal, such as aluminum. The chamber body 106 may be grounded via a coupling to ground 115.

A substrate support 124 is disposed within the chamber interior volume 120 to support and retain a substrate S, such as a semiconductor wafer, for example, or other such substrate as may be electrostatically retained. The substrate support 124 may generally comprise an electrostatic chuck 150 and a hollow support shaft 112 for supporting the electrostatic chuck 150. The hollow support shaft 112 provides a conduit to provide, for example, process gases, fluids, coolants, power, or the like, to the electrostatic chuck 150.

In some embodiments, the hollow support shaft 112 is coupled to a lift mechanism 113 which provides vertical movement of the electrostatic chuck 150 between an upper, processing position (as shown in FIG. 1) and a lower, transfer position (not shown). A bellows assembly 110 is disposed about the hollow support shaft 112 and is coupled between the electrostatic chuck 150 and a bottom surface 126 of chamber 100 to provide a flexible seal that allows vertical motion of the electrostatic chuck 150 while preventing loss of vacuum from within the chamber 100. The bellows assembly 110 also includes a lower bellows flange 164 in contact with an O-ring 165 or other suitable sealing element which contacts bottom surface 126 to help prevent loss of chamber vacuum.

The hollow support shaft 112 provides a conduit for coupling a fluid source 142, a gas supply 141, a chucking power supply 140, and RF sources (e.g., RF plasma power supply 170 and RF bias power supply 117) to the electrostatic chuck 150. In some embodiments, RF plasma power supply 170 and RF bias power supply 117 are coupled to the electrostatic chuck via respective RF match networks (only RF match network 116 shown).

A substrate lift 130 may include lift pins 109 mounted on a platform 108 connected to a shaft 111 which is coupled to a second lift mechanism 132 for raising and lowering the substrate lift 130 so that the substrate “S” may be placed on or removed from the electrostatic chuck 150. The electrostatic chuck 150 includes thru-holes to receive the lift pins 109. A bellows assembly 131 is coupled between the substrate lift 130 and bottom surface 126 to provide a flexible seal which maintains the chamber vacuum during vertical motion of the substrate lift 130.

The chamber 100 is coupled to and in fluid communication with a vacuum system 114 which includes a throttle valve (not shown) and vacuum pump (not shown) which are used to exhaust the chamber 100. The pressure inside the chamber 100 may be regulated by adjusting the throttle valve and/or vacuum pump. The chamber 100 is also coupled to and in fluid communication with a process gas supply 118 which may supply one or more process gases to the chamber 100 for processing a substrate disposed therein.

In operation, for example, a plasma 102 may be created in the chamber interior volume 120 to perform one or more processes. The plasma 102 may be created by coupling power from a plasma power source (e.g., RF plasma power supply 170) to a process gas via one or more electrodes proximate to or within the chamber interior volume 120 to ignite the process gas and creating the plasma 102. In some embodiments, a bias power may also be provided from a bias power supply (e.g., RF bias power supply 117) to one or more electrodes (described below) disposed within the electrostatic chuck 150 to attract ions from the plasma towards the substrate S.

In some embodiments, for example where the chamber 100 is a PVD chamber, a target 166 comprising a source material to be deposited on a substrate S may be disposed above the substrate and within the chamber interior volume 120. The target 166 may be supported by a grounded conductive portion of the chamber 100, for example an aluminum adapter through a dielectric isolator. In other embodiments, the chamber 100 may include a plurality of targets in a multi-cathode arrangement for depositing layers of different material using the same chamber.

A controllable DC power source 168 may be coupled to the chamber 100 to apply a negative voltage, or bias, to the target 166. The RF bias power supply 117 may be coupled to the substrate support 124 in order to induce a negative DC bias on the substrate S. In addition, in some embodiments, a negative DC self-bias may form on the substrate S during processing. In some embodiments, an RF plasma power supply 170 may also be coupled to the chamber 100 to apply RF power to the target 166 to facilitate control of the radial distribution of a deposition rate on substrate S. In operation, ions in the plasma 102 created in the chamber 100 react with the source material from the target 166. The reaction causes the target 166 to eject atoms of the source material, which are then directed towards the substrate S, thus depositing material.

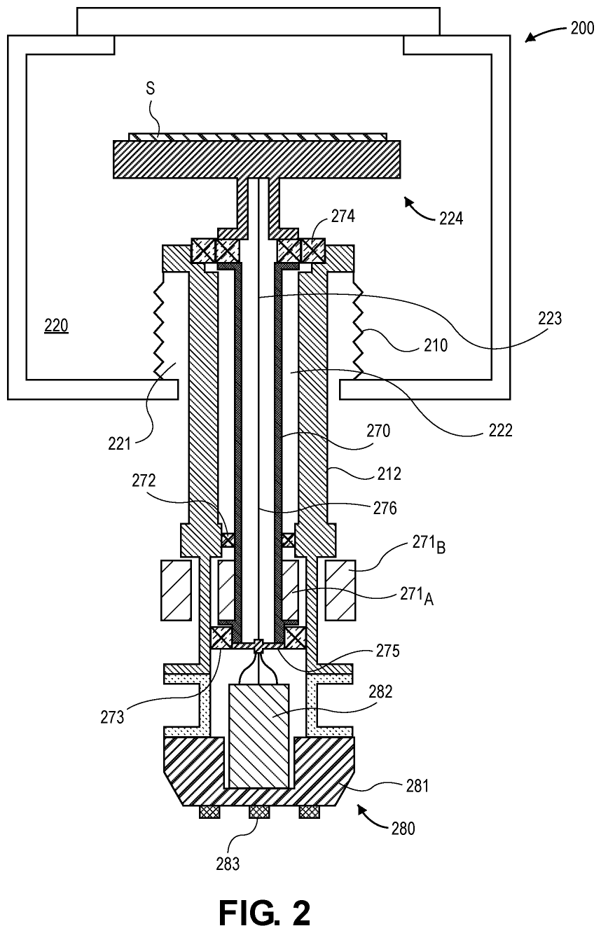

Referring now to FIG. 2, a cross-sectional illustration of a chamber 200 with more detail of the pedestal 224 and associated components is shown, in accordance with an embodiment. As shown, the pedestal 224 may support a substrate S in the chamber 200. The pedestal 224 may comprise one or more sub-components (not shown for simplicity). For example, the pedestal 224 may comprise one or more electrostatic chucking electrodes, biasing electrodes, and/or heating elements.

An interior volume 220 of the chamber 200 may be configured to be maintained at a sub-atmospheric pressure using throttle valves, vacuum pumps, and the like. Such components are omitted from FIG. 2 for simplicity. In an embodiment, a pressure within the interior volume 220 may be approximately 100 Tor or less. In a particular embodiment, the pressure within the interior volume 220 may be between approximately 3 Tor and approximately 100 Tor. In an embodiment, a first shaft 212 may pass through a bottom of the chamber 200. In order to maintain the seal of the chamber 200, a baffle structure 210 may be provided between the first shaft 212 and the chamber 200. That is, a region 221 between the exterior of the baffle structure 210 and the first shaft 212 is at atmospheric pressure. The baffle structure 210 allows for the pedestal 224 to be vertically displaced, by a lift mechanism, such as the one described in greater detail above.

In an embodiment, the first shaft 212 may sometimes be referred to as a stationary shaft 212. That is, the first shaft 212 may remain stationary while a second shaft 270 within the first shaft 212 is rotated. The rotation of the second shaft 270 relative to the first shaft 212 may be aided by the presence of one or more bearings 272, 273, and 274 between the first shaft 212 and the second shaft 270. In a particular embodiment, the bearing 274 may be a cross-roller bearing 274. In an embodiment, a region 222 between the exterior of the second shaft 270 and an interior of the first shaft 212 may be held at the sub-atmospheric pressure (which may be referred to as a vacuum pressure). In a particular embodiment, the region 222 may have a pressure less than 10 Tor. For example, the region 222 may have a pressure between approximately 1 Tor and approximately 10 Tor.

In an embodiment, the second shaft 270 may be rotated with any suitable driving architecture. In the particular embodiment shown in FIG. 2, the driving architecture is a magnetic architecture. As shown, one or more interior magnets 271_{A} are attached to the second shaft 270 and outer magnets 271_{B} are provided outside of the first shaft 212. In an embodiment, the outer magnets 271_{B} are rotated around the first shaft 212 with any suitable mechanism. For example the outer magnets 271_{B} may be driven by a belt drive or a motor (not shown). Rotating the outer magnets 271_{B} drives the inner magnets 271_{A}, the second shaft 270, and the pedestal 224. Because the inner magnet 271_{A} is disposed within the first shaft 212, the inner magnet 271_{A} is at vacuum pressure, and because the outer magnet 271_{B} is disposed outside of the first shaft 212, the outer magnet 271_{B} is at atmospheric pressure. However, both the inner magnet 271_{A} and the outer magnet 271_{B} may instead be disposed within the first shaft 212.

In an embodiment, a plurality of wires 276 may be fed through a vacuum feedthrough 275. While a single wire 276 is shown within the second shaft 270, it is to be appreciated that two or more wires 276 may pass through the vacuum feedthrough 275 and into the second shaft 270. The interior volume 223 of the second shaft 270 may be at atmospheric pressure in some embodiments. In some embodiments, the interior volume 223 may be at a pressure higher than atmospheric pressure. The higher pressure (e.g., at atmospheric pressure or above) prevents breakdown within the interior volume 223.

In an embodiment, the wires 275 may extend out of an RF rotary feedthrough 280. The RF rotary feedthrough 280 may include a stator 281 and a rotor 282. That is, the stator 281 remains stationary (coupled to the outer first shaft 212), and the rotor 282 is free to rotate with the inner second shaft 270. The RF rotary feedthrough 280 may have any number of electrical pathways that allow for propagating power across a junction between a stationary component (i.e., the stator 281) and a rotating component (i.e., the rotor 282). The construction of the RF rotary feedthrough 280 allows for high current to pass across the boundary between rotating and stationary components. As such, one or more of the wires 275 may be used to feed heating elements (not shown) in the pedestal 224. In some instances, the RF rotary feedthrough 280 may have a slip-ring type structure. Contacts 283 may be provided on a bottom of the stator 281. While referred to as an RF rotary feedthrough, it is to be appreciated that other electric current from 0 GHz to 100 GHz may be propagated through the RF rotary feedthrough 280.

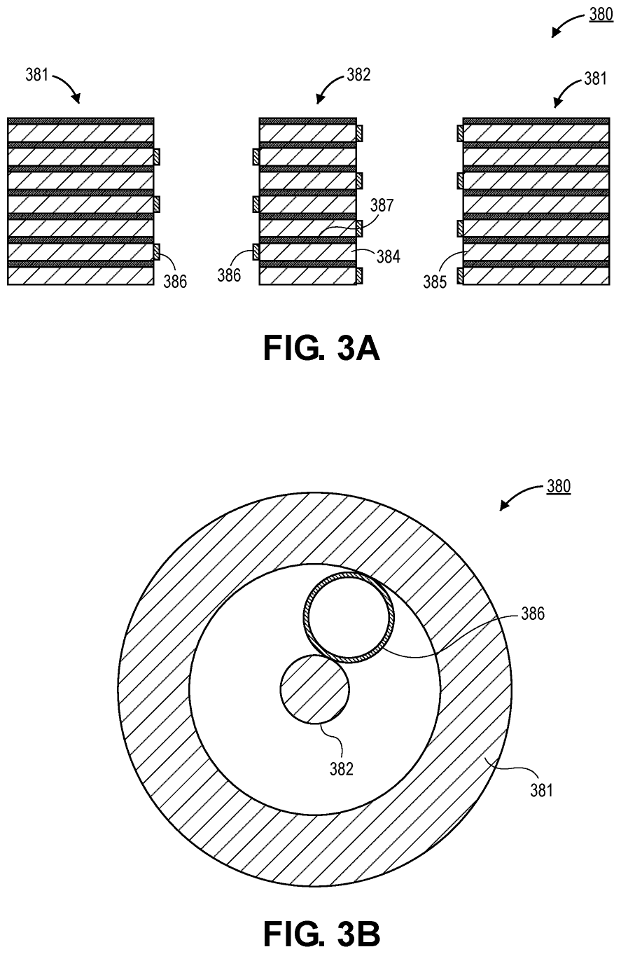

Referring now to FIG. 3A, a cross-sectional illustration of an RF rotary feedthrough 380 is shown, in accordance with an embodiment. As shown, the rotor 382 is provided within a center of the stator 381. The rotor 382 may comprise a plurality electrically conductive layers 384. The layers 384 may be electrically isolated from each other by insulating layers 387. While not shown for simplicity, each of the electrically conductive layers 384 may be coupled to a top surface of the rotor 382 by vias through a thickness of the rotor 382.

Similarly, the stator 381 may comprise a plurality of electrically conductive layers 385. The number of electrically conductive layers 385 may be equal to the number of electrically conductive layers 384 in the rotor 382. The layers 385 may be electrically isolated from each other by insulating layers 387. In an embodiment, the electrically conductive layers 384 may be coupled to a bottom surface of the stator 381 by vias (not shown) through a thickness of the stator 381.

In order to provide connections between the stationary layers 385 and the rotating layers 384, a plurality of conductive connector rings 386 may be provided. For example, copper rings or the like may be secured between ends of the layers 385 and ends of the layers 384. As the center rotor 382 rotates, the connector rings 386 rotate and maintain an electrical connection between the stator 381 and the rotor 382. In the illustrated embodiment, a set of seven connector rings 386 are shown, one for each of the layers 384 and 385. However, it is to be appreciated that the RF rotary feedthrough may include any number of connector rings 386 (e.g., one or more rings 386).

The structure of the connector rings 386 may be more clearly illustrated in FIG. 3B. As shown, a layer of the stator 381 and a layer of the rotor 382 are provided. The stator 381 forms a ring around the rotor 382, which may be a disc. In an embodiment, the connector ring 386 may be provided between an outer edge of the disc for the rotor 382 and an inner edge of the ring for the stator 381. In some embodiment, the distance between the edge of the disc and an inner surface of the ring may be substantially equal to a diameter of the connector ring 386. However, in some embodiments, the diameter of the connector ring 386 may be slightly larger than the distance between the edge of the disc and an inner surface of the ring. As such, the connector ring 386 may be slightly deformed so that it is not a perfect circle. As the disc of the rotor 382 rotates, the connector ring 386 will rotate in the opposite direction. For example, if the disc rotates clockwise, the connector ring 386 will rotate counter clockwise.

In FIGS. 3A and 3B, a generic example of an RF rotary feedthrough is shown, in accordance with an embodiment. However, it is to be appreciated that many different configurations of the RF rotary feedthrough may be used in order to fabricate semiconductor processing tools, such as those described herein.

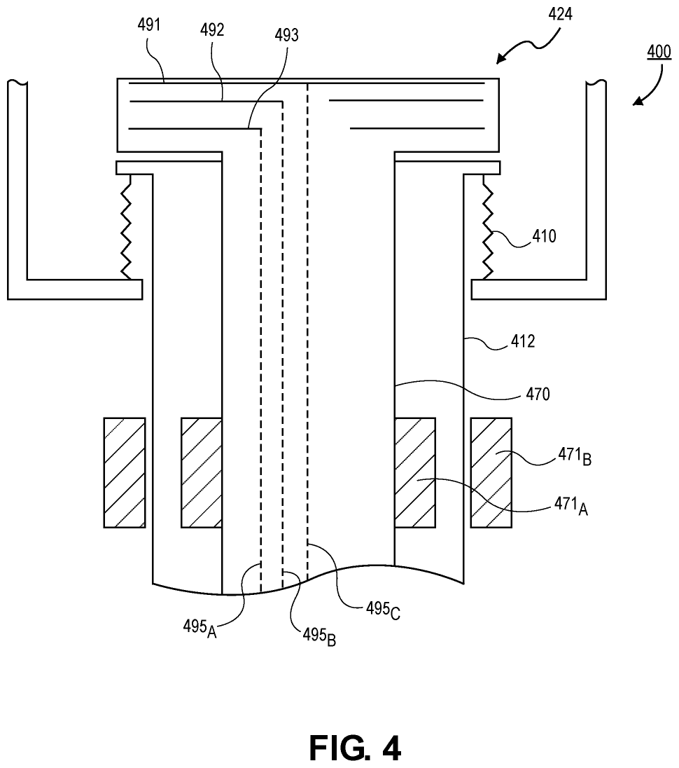

Referring now to FIG. 4, a schematic cross-sectional illustration of chamber 400 is shown, in accordance with an embodiment. The illustrated embodiment is simplified in complexity in order to more clearly illustrate the electrical components of the pedestal 424. As shown, the pedestal 424 may be coupled to an inner shaft 470. An outer shaft 412 may surround the inner shaft 470. The outer shaft 412 may be a stationary component in that it does not rotate. However, in some embodiments, the outer shaft 412 may be displaced vertically. As such, a bellows assembly 410 may connect the outer shaft 412 to the chamber 400 in order to keep a vacuum seal of the chamber 400.

As shown in FIG. 4, a rotation assembly may be provided along the length of the shafts 412 and 470. Similar to the embodiments described in greater detail above, one or more inner magnets 471_{A} may be mechanically coupled to the inner shaft 470. One or more outer magnets 471_{B} may be provided around the outer shaft 412. Rotating the outer magnets 471_{B} (e.g., with a drive belt or the like) results in the inner magnets 471_{A} rotating. This drives rotation of the inner shaft 470 and the pedestal 424.

As shown in FIG. 4, a plurality of conductive wires 495_{A}-495_{C} may be provided through the center of the inner shaft 412. The wires 495 may be coupled to an RF rotary feedthrough (not shown in FIG. 4) that allows for free rotation of the wires 495 even though they are ultimately coupled to a stationary component. In an embodiment, a first wire 495_{A} may be coupled to a heating element 493 in the pedestal 424. The heating element 493 may be a resistive heating feature, lamps, or the like. In an embodiment, the heating element 493 may include a plurality of zones (e.g., an inner zone and an outer zone). In such embodiments, multiple wires 495 may be connected to the heating element 493 in order to independently control the different zones. In an embodiment, a second wire 495_{B} may be coupled to a biasing electrode 492. In an embodiment, the biasing electrode 492 allows for the pedestal (and a substrate) to be biased in order to attract ions in the plasma or the like. In an embodiment, a third wire 495_{C} may be coupled to an electrostatic chucking electrode 491. In an embodiment, the electrostatic chucking electrode 491 may be a single electrode or a comprise two or more electrodes (e.g., to enable bipolar chucking architectures).

While three wires 495 are shown, it is to be appreciated that any number of wires 495 may be used. The number of wires 495 may match the number of connector rings in the RF rotary feedthrough. In a particular embodiment, seven wires 495 are fed through the inner shaft 470. Four out of the seven wires 495 may be used for the heating element (e.g., to support two zones), a fifth wire 495 may be used for electrostatic chucking electrode 491, a sixth wire 495 may be used to provide RF power to the biasing electrode 492, and a seventh wire 495 may be used to probe the backside of the substrate to determine the center tap for the electrostatic chucking power supply.

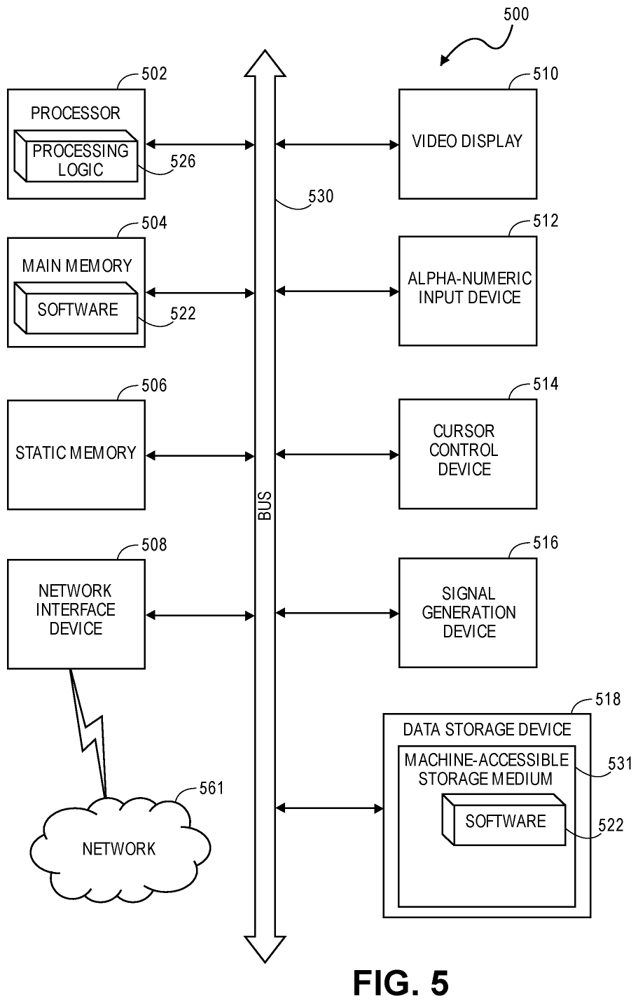

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 532 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 520 via the system network interface device 508. In an embodiment, the network interface device 508 may operate using RF coupling, optical coupling, acoustic coupling, or inductive coupling.

While the machine-accessible storage medium 532 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An electrostatic chuck, comprising:
a pedestal with a support surface for supporting a substrate and a second surface opposite from the support surface;
a chucking electrode within the pedestal;
a biasing electrode within the pedestal;
a heating element within the pedestal;
a shaft coupled to the second surface of the pedestal; and
a rotation assembly coupled to the shaft to rotate the shaft and the pedestal.

2. The electrostatic chuck of claim 1, wherein the rotation assembly is a magnetically driven rotation assembly.

3. The electrostatic chuck of claim 1, wherein the shaft rotates the pedestal, the chucking electrode, the biasing electrode, and the heating device.

4. The electrostatic chuck of claim 1, wherein the heating element comprises resistive heating elements.

5. The electrostatic chuck of claim 1, wherein the heating element comprises a plurality of lamps.

6. The electrostatic chuck of claim 1, wherein the electrostatic chuck is at least partially within a chamber.

7. The electrostatic chuck of claim 6, wherein the shaft is within an outer shaft that does not rotate.

8. The electrostatic chuck of claim 7, wherein the interior of the shaft is configured to be at atmospheric pressure, and a volume between shaft and the interior of the outer shaft is configured to be at a vacuum pressure.

9. The electrostatic chuck of claim 1, further comprising:
a lifting unit coupled to the shaft, wherein the lifting unit is configured to vertically displace the pedestal.

10. The electrostatic chuck of claim 1, wherein seven wires extend up the shaft to contact the chucking electrode, the biasing electrode, and the heating element.

11. The electrostatic chuck of claim 10, wherein the wires are coupled to a slip-ring connector in order to allow for rotation of the wires.

12. A semiconductor tool, comprising:
a chamber;
a first shaft through the chamber, wherein a baffle between the first shaft and the chamber seals the chamber;
a second shaft within the first shaft;
a pedestal over a first end of the second shaft within the chamber; and
a rotation assembly coupled to the second shaft to rotate the second shaft and the pedestal relative to the first shaft.

13. The semiconductor tool of claim 12, wherein the rotation assembly is a magnetic drive assembly.

14. The semiconductor tool of claim 13, wherein a first magnet is attached to the second shaft, and wherein a second magnet is magnetically coupled to the first magnet, and wherein the second magnet is outside the first shaft.

15. The semiconductor tool of claim 12, further comprising a rotating electrical feedthrough below the first shaft and the second shaft.

16. The semiconductor tool of claim 15, wherein the rotating electrical feedthrough is a slip-ring feedthrough.

17. The semiconductor tool of claim 15, wherein conductive wires pass from the rotating electrical feedthrough to components in the pedestal.

18. The semiconductor tool of claim 17, wherein the components in the pedestal comprise a chucking electrode, a bias electrode, and a heating element.

19. A semiconductor tool, comprising:
a chamber;
a pedestal within the chamber, wherein the pedestal comprises a chucking electrode, a bias electrode, and a heating element;
a first shaft through a bottom of the chamber;
a second shaft through the bottom of the chamber and within the first shaft, wherein the pedestal is coupled to the second shaft;
a baffle between a portion of the first shaft and the chamber to seal the chamber;
a vacuum feedthrough at an end of the second shaft opposite from the pedestal; and
a radio frequency (RF) rotary feedthrough below the vacuum feedthrough.

20. The semiconductor tool of claim 19, wherein the RF rotary feedthrough is a slip-ring feedthrough.
